(19) United States
(12) Patent Application Publication
(10) Pub. No.: US 2026/0047145 A1
(43) Pub. Date: Feb. 12, 2026

(54) STACKED MULTI-CHANNEL STRUCTURE AND METHOD FOR MANUFACTURING SAME, AND THIN FILM TRANSISTOR COMPRISING SAME

(71) Applicant: IUCF-HYU (INDUSTRY-UNIVERSITY COOPERATION FOUNDATION HANYANG UNIVERSITY ), Seoul (KR)

(72) Inventors: Jin Seong PARK, Seongnam-si (KR); Won Bum Lee, Seoul (KR); Yoon Seo Kim, Seoul (KR)

(73) Assignee: IUCF-HYU (INDUSTRY-UNIVERSITY COOPERATION FOUNDATION HANYANG UNIVERSITY ), Seoul (KR)

(21) Appl. No.: 19/359,065

(22) Filed: Oct. 15, 2025

Related U.S. Application Data
(63) Continuation of application No. PCT/KR2024/004623, filed on Apr. 8, 2024.

(30) Foreign Application Priority Data
Apr. 18, 2023 (KR) 10-2023-0050395

(51) Int. Cl. H10D 30/67; H10D 30/01

(52) U.S. Cl. CPC H10D 30/6757; H10D 30/031; H10D 30/6755

(57) ABSTRACT

A thin film transistor is provided. The thin film transistor may comprise a stacked channel structure in which a first material layer including an oxide semiconductor and a second material layer including a metal oxide insulator are stacked, wherein the channel structure forms a multi-channel by stacking a plurality of stacks each having the first material layer and the second material layer stacked, and as the number of the stacks stacked increases, mobility and subthreshold swing may increase.

### TECHNICAL FIELD

The present invention relates to a stacked multi-channel structure in which an oxide semiconductor and a metal oxide insulator are stacked, a method for manufacturing the same, and a thin film transistor including the same.

### BACKGROUND ART

TFTs constitute a back-plane that controls a flow of a current to drive a display panel. Currently, types of TFTs used in the display industry are determined by semiconductor materials, and include amorphous silicon (a-Si) TFTs, low-temperature poly-silicon (LTPS) TFTs, and amorphous oxide TFTs. Among these, oxide semiconductor TFTs are used in display back-planes and considered as promising candidates in the memory/system semiconductor field due to relatively high mobility and extremely low leakage current characteristics.

However, in the display field, since the TFTs with low leakage current characteristics and high subthreshold swing (SS) during threshold voltage (Vₜₕ) shifts caused by reliability deterioration have less variations in drain currents, the TFTs may maintain switching characteristics longer, which allows the TFT to be a technology that is attracting attention. Furthermore, higher mobility is required to replace LTPS. Therefore, researches on various oxide semiconductors are being conducted to implement oxide semiconductor TFTs having high mobility characteristics and capable of controlling SS.

Conventional researches on stacked thin film transistors in which oxide semiconductors are applied to obtain high mobility characteristics have been conducted based on physical deposition schemes such as sputtering. Such a sputtering deposition process, which is mainly used commercially, has limitations in controlling nanoscale thicknesses due to physical deposition and limitations in controlling positive ion compositions due to fixed target compositions, so that the sputtering deposition process has difficulties in researching the stacked thin film transistors. Conventional representative stacked structures have improved mobility by locating materials with high mobility in a front-channel and locating stable materials with relatively low mobility in a back-channel. In addition, in order to achieve high mobility characteristics, the stacked structures have improved mobility by performing heterojunction on two materials with large conduction band offsets to form a two-dimensional electron gas (2DEG) at an interface.

However, although the mobility improvement may be achieved through the conventional stacked structures, there are difficulties in controlling SS values. In particular, a negative shift of a threshold voltage may be easily caused by bound electrons in a 2DEG structure.

### DISCLOSURE

### Technical Problem

One technical object of the present invention is to provide a stacked multi-channel structure, a method for manufacturing the same, and a thin film transistor including the same.

Another technical object of the present invention is to provide a multi-channel structure in which an oxide semiconductor and a metal oxide insulator are stacked, a method for manufacturing the same, and a thin film transistor including the same.

Still another technical object of the present invention is to provide a multi-channel structure capable of easily controlling a thickness and a composition of a channel, a method for manufacturing the same, and a thin film transistor including the same.

Yet another technical object of the present invention is to provide a multi-channel structure capable of easily controlling mobility and subthreshold swing, a method for manufacturing the same, and a thin film transistor including the same.

Still yet another technical object of the present invention is to provide a multi-channel structure capable of maintaining a threshold voltage to be substantially constant while mobility and subthreshold swing are controlled, a method for manufacturing the same, and a thin film transistor including the same.

Technical objects of the present invention are not limited to the technical objects described above.

### Technical Solution

To achieve the technical objects described above, the present invention provides a thin film transistor.

According to one embodiment, there is provided a thin film transistor including a channel structure in which a first material layer including an oxide semiconductor and a second material layer including a metal oxide insulator are stacked, wherein the channel structure forms a multi-channel by stacking a plurality of stacks, in which the first material layer and the second material layer are stacked in each of the stacks, and mobility and subthreshold swing increase as a stacking number of the stacks increases.

According to one embodiment, an increase rate of the mobility according to the increase in the stacking number of the stacks may be higher than an increase rate of the subthreshold swing.

According to one embodiment, a variation in a threshold voltage may be maintained at 10% or less even when the stacking number of the stacks increases.

According to one embodiment, the threshold voltage may be maintained in a range of 0.09 V to 0.19 V even when the stacking number of the stacks increases.

According to one embodiment, the stacking number of the stacks may be greater than equal to 5, and less than or equal to 10.

According to one embodiment, a thickness of the second material layer may be less than 4 nm.

According to one embodiment, the oxide semiconductor may include indium gallium zinc oxide (IGZO).

According to one embodiment, the metal oxide insulator may include aluminum oxide (Al₂O₃).

According to one embodiment, an amount of movement of carriers within the first material layer that is arranged relatively close to a gate may be greater than an amount of movement of carriers within the first material layer that is arranged relatively far from the gate.

To achieve the technical objects described above, the present invention provides a method for manufacturing a channel structure.

According to one embodiment, the method for manufacturing the channel structure includes: preparing a substrate; forming a first material layer including an oxide semiconductor on the substrate by a plasma-enhanced atomic layer deposition (PEALD) process; and forming a second material layer including a metal oxide insulator on the first material layer by a PEALD process, wherein the forming of the first material layer and the forming of the second material layer are alternately repeated so as to form a multi-channel.

According to one embodiment, the forming of the first material layer may include: reacting an indium (In) precursor, a gallium (Ga) precursor, a zinc (Zn) precursor, and oxygen plasma (O₂ plasma) on the substrate, and the forming of the second material layer may include: reacting an aluminum (Al) precursor and oxygen plasma (O₂ plasma) on the first material layer. According to one embodiment, the first material layer and the second material layer may be formed by an in-situ process.

### Advantageous Effects

According to an embodiment of the present invention, a thin film transistor may include a channel structure in which a first material layer including an oxide semiconductor (e.g., IGZO) and a second material layer including a metal oxide insulator (e.g., Al₂O₃) are stacked, wherein the channel structure forms a multi-channel by stacking a plurality of stacks, in which the first material layer and the second material layer are stacked in each of the stacks.

In addition, since the channel structure is manufactured through a PEALD process, a thickness and a composition can be easily controlled, and a high mobility characteristic can be effectively expressed through the control of the thickness and the composition.

In addition, subthreshold swing (SS) can be easily controlled, and a threshold voltage (Vₜₕ) can be maintained substantially constant despite controlling mobility (UEE) and the subthreshold swing (SS). Accordingly, the channel structure can be easily applied to transistors in display back-planes that require high mobility and high reliability.

### DESCRIPTION OF DRAWINGS

FIG. 1 is a flowchart for describing a method for manufacturing a channel structure according to an embodiment of the present invention.

FIG. 2 is a view for specifically describing a step S200 of the method for manufacturing the channel structure according to the embodiment of the present invention.

FIG. 3 is a view for specifically describing a step S300 of the method for manufacturing the channel structure according to the embodiment of the present invention.

FIG. 4 is a view for describing the channel structure according to the embodiment of the present invention.

FIG. 5 is a view for describing a thin film transistor according to an embodiment of the present invention.

FIG. 6 is a schematic view showing a T-T′ section of FIG. 5.

FIG. 7 is a view for describing various forms of a channel structure included in the thin film transistor according to the embodiment of the present invention.

FIG. 8 is a STEM image of a channel structure according to an experimental example of the present invention.

FIGS. 9 and 10 are views for describing EDS analysis results of the channel structure according to the experimental example of the present invention.

FIG. 11 is a view for describing electrical characteristics of thin film transistors according to Experimental Examples 1-1 to 1-4 of the present invention.

FIG. 12 is a view for comparing TCAD simulation results of thin film transistors according to Experimental Examples 1-1 to 1-9 of the present invention.

FIG. 13 is a view for describing electrical characteristics of thin film transistors according to Experimental Examples 2-1 to 2-6 of the present invention.

FIG. 14 is a view for describing simulation results of thin film transistors according to Experimental Examples 3-1 to 3-3 of the present invention.

FIG. 15 is a view for describing simulation results of thin film transistors according to Experimental Examples 4-1 to 4-3 of the present invention.

FIG. 16 is a view for describing simulation results of thin film transistors according to Experimental Examples 5-1 to 5-3 of the present invention.

FIG. 17 is a graph for comparing electrical characteristics according to a k value of an insulator.

FIGS. 18 and 19 are views for comparing amounts of movement of carriers within channel structures of the thin film transistors according to Experimental Examples 1-1 to 1-4 of the present invention.

### MODE FOR INVENTION

Hereinafter, exemplary embodiments of the present invention will be described in detail with reference to the accompanying drawings. However, the technical idea of the present invention is not limited to the embodiments described herein, but may be embodied in different forms. The embodiments introduced herein are provided to sufficiently deliver the idea of the present invention to those skilled in the art so that the disclosed contents may become thorough and complete.

When it is mentioned in the present disclosure that one element is on another element, it means that one element may be directly formed on another element, or a third element may be interposed between one element and another element. Further, in the drawings, thicknesses of films and regions are exaggerated for effective description of the technical contents.

In addition, although the terms such as first, second, and third have been used to describe various elements in various embodiments of the present disclosure, the elements are not limited by the terms. The terms are used only to distinguish one element from another element. Therefore, an element mentioned as a first element in one embodiment may be mentioned as a second element in another embodiment. The embodiments described and illustrated herein include their complementary embodiments, respectively. Further, the term “and/or” used in the present disclosure is used to include at least one of the elements enumerated before and after the term.

As used herein, an expression in a singular form includes a meaning of a plural form unless the context clearly indicates otherwise. Further, the terms such as “including” and “having” are intended to designate the presence of features, numbers, steps, elements, or combinations thereof described herein, and shall not be construed to preclude any possibility of the presence or addition of one or more other features, numbers, steps, elements, or combinations thereof. In addition, the term “connection” used herein is used to include both indirect and direct connections of a plurality of elements.

Further, in the following description of the present invention, detailed descriptions of known functions or configurations incorporated herein will be omitted when they may make the gist of the present invention unnecessarily unclear.

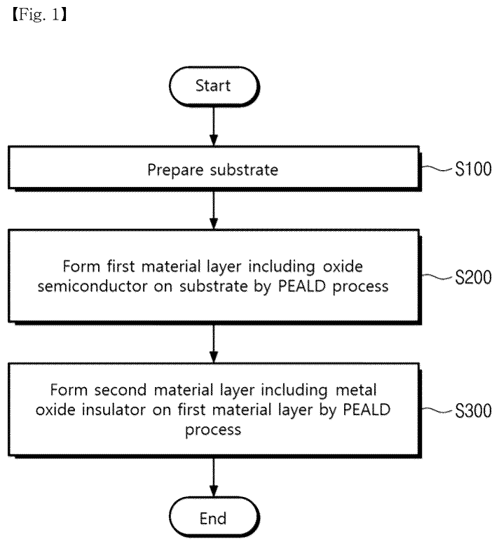

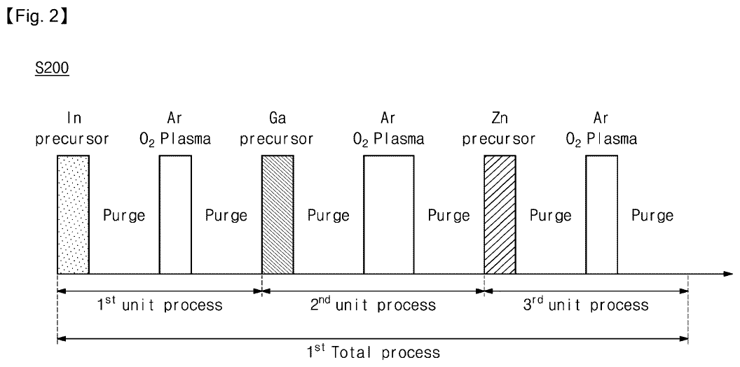

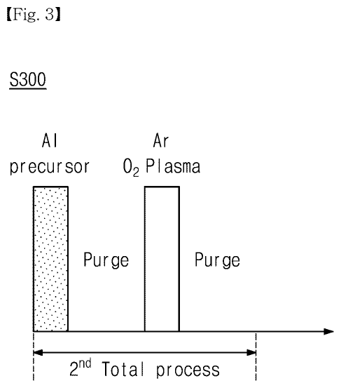

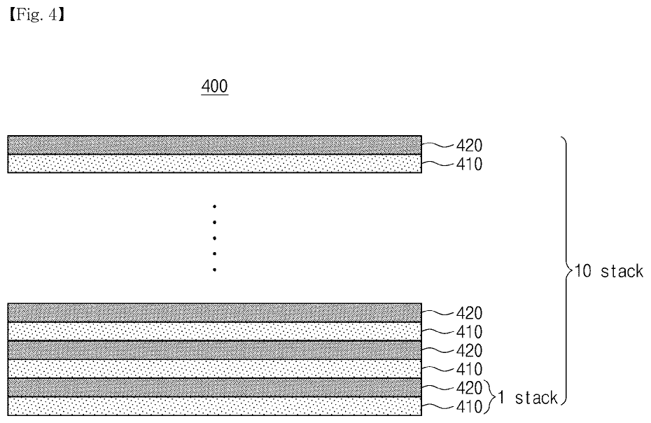

FIG. 1 is a flowchart for describing a method for manufacturing a channel structure according to an embodiment of the present invention, FIG. 2 is a view for specifically describing a step S200 of the method for manufacturing the channel structure according to the embodiment of the present invention, FIG. 3 is a view for specifically describing a step S300 of the method for manufacturing the channel structure according to the embodiment of the present invention, and FIG. 4 is a view for describing the channel structure according to the embodiment of the present invention.

Referring to FIGS. 1 to 4, a substrate may be prepared (S100). According to one embodiment, the substrate may be a silicon semiconductor substrate. Alternatively, according to another embodiment, the substrate may be one of a compound semiconductor substrate, a glass substrate, or a plastic substrate. A type of the substrate is not limited.

A first material layer 410 including an oxide semiconductor may be formed on the substrate by a plasma-enhanced atomic layer deposition (PEALD) process (S200). According to one embodiment, the first material layer 410 may be formed by reacting an indium (In) precursor, a gallium (Ga) precursor, a zinc (Zn) precursor, and oxygen plasma (O₂ plasma). Accordingly, the first material layer 410 may include indium gallium zinc oxide (IGZO). In other words, the oxide semiconductor included in the first material layer 410 may be IGZO.

In more detail, as shown in FIG. 2, the first material layer 410 may be formed by sequentially performing an indium precursor provision step (In precursor), a purge step (Purge), an oxygen plasma provision step (O₂ plasma), a purge step (Purge), a gallium precursor provision step (Ga precursor), a purge step (Purge), an oxygen plasma provision step (O₂ plasma), a purge step (Purge), a zinc precursor provision step (Zn precursor), a purge step (Purge), an oxygen plasma provision step (O₂ plasma), and a purge step (Purge).

For example, the indium precursor may include (3-dimethylaminopropyl)dimethylindium (DADI). For another example, the indium precursor may include one of trimethyl indium (TMI), triethyl indium (TEI), bis(trimethysilyl)amidodiethyl indium (InCA-1), cyclopentadienylindium (CpIn), tris(2,2,6,6-tetramethyl-3,5-heptanedionato) indium (III) (In(tmhd)₃), indium (III) acetylacetonate (In(acac)₃), (dimethylbutylamino) trimethylindium (DATI), dimethyl(nethoxy-2,2-dimethylpropanamido) indium (Me₂In(EDPA)), ethylcyclopentadienyl indium (InEtCp), trimethyl[N-(2-methoxyethyl)-2-methylpropan-2-amine]indium (TMION), dimethyl[N-(tert-butyl)-2-methoxy-2-methylpropan-1-amine]indium (DMION), dimethyl[N1-(tert-butyl)-N2,N2-dimethylethane-1,2-diamine]indium (DMITN), tris-(N,N′-diisopropyl-2-diethylamido-guanidinato)-indium (III) (In[(iPr)₂CNEt₂]₃), tris-(N,N′-diisopropyl-2-dimethylamido-guanidinato)-indium (III) (In[(iPr)₂CNMe₂]₃), diethyl[bis(trimethylsilyl)amido]indium (Et₂InN(SiMe₃)₂), tris(1-dimethylamino-2-methyl-2-propoxy) indium (In(dmamp)₃), and tris(N,N′-diisopropylacetamidinato) indium (III).

For example, the gallium precursor may include trimethylgallium r example, the gallium precursor may include one of triethyl gallium (TEGa), gallium acetylacetonate (Ga(acac)₃), dimethylgallium amide ([(CH₃)₂GaNH₂]₃), hexakis (dimethylamido) digallium (Ga₂(NMe₂)₆), dimethylgallium isopropoxide (Me₂GaOiPr), gallium tri-isopropoxide (Ga(OiPr)₃), tris(2,2,6,6-tetramethyl-3,5-heptanedionato) gallium (III) (Ga(TMHD)₃), pentamethylcyclopentadienyl gallium (GaCp), gallium 2,2,6,6-tetramethyl-3,5-heptanedionate (Ga(thd)₃), trimethyl[N-(2-methoxyethyl)-2-methylpropan-2-amine]gallium (TMGON), dimethyl[N-(tert-butyl)-2-methoxy-2-methylpropan-1-amine]gallium (DMGON), and dimethyl[N1-(tert-butyl)-N2,N2-dimethylethane-1,2-diamine]gallium (DMGTN).

For example, the zinc precursor may include diethylzinc (DEZ). For another example, the zinc precursor may include one of dimethylzinc (DMZ), zinc chloride (ZnCl₂), zinc acetate (Zn(CH₃COO)₂), bis[4-((2-ethoxyethyl) imino)-pent-2-en-2-olate]zinc (Zn(eeki)₂), and bis-3-(N, N-dimethylamino) propyl zinc (BDMPZ).

According to one embodiment, the indium precursor provision step (In precursor), the purge step (Purge), the oxygen plasma provision step (O₂ plasma), and the purge step (Purge) may be defined as a first unit process (1^{st} unit process). Meanwhile, the gallium precursor provision step (Ga precursor), the purge step (Purge), the oxygen plasma provision step (O₂ plasma), and the purge step (Purge), may be defined as a second unit process (2^{nd} unit process). Meanwhile, the zinc precursor provision step (Zn precursor), the purge step (Purge), the oxygen plasma provision step (O₂ plasma), and the purge step (Purge) may be defined as a third unit process (3^{rd} unit process). In addition, the first to third unit processes may be defined as a first total process (1^{st} total process).

Each of the first to third unit processes may be repeatedly performed a plurality of times. The first total process may also be repeatedly performed a plurality of times. The number of repetitions of each of the first to third unit processes and the number of repetitions of the first total process may be controlled, so that a thickness of the first material layer 410 may be controlled.

As described above, the thickness of the first material layer 410 may be controlled by controlling the number of repetitions of the first total process, so that the thickness of the first material layer 410 may be easily controlled. In addition, the number of repetitions of each of the first to third unit processes may be controlled, so that a composition of indium (In), gallium (Ga), and zinc (Zn) within the first material layer 410 may be easily controlled.

A second material layer 420 including a metal oxide insulator may be formed on the first material layer 410 by a plasma-enhanced atomic layer deposition (PEALD) process (S300).

According to one embodiment, the second material layer 420 may be formed by reacting an aluminum (Al) precursor and oxygen plasma (O₂ plasma). Accordingly, the second material layer 420 may include aluminum oxide (Al₂O₃). In other words, the metal oxide insulator included in the second material layer 420 may be aluminum oxide (Al₂O₃).

In more detail, as shown in FIG. 3, the second material layer 420 may be formed by sequentially performing an aluminum precursor provision step (Al precursor), a purge step (Purge), an oxygen plasma provision step (O₂ plasma), and a purge step (Purge). For example, the aluminum precursor may include trimethyl aluminum (TMA).

According to one embodiment, the aluminum precursor provision step (Al precursor), the purge step (Purge), the oxygen plasma provision step (O₂ plasma), and the purge step (Purge) may be defined as a second total process (2^{nd} total process). The second total process may be repeatedly performed a plurality of times. The number of repetitions of the second total process may be controlled, so that a thickness of the second material layer 420 may be controlled.

According to one embodiment, multi-channel characteristics of a channel structure 400 that will be described below may be controlled according to the thickness of the second material layer 420. In detail, the thickness of the second material layer 420 may be controlled to be less than 4 nm, so that the multi-channel characteristics of the channel structure 400 that will be described below may be expressed. On the contrary, when the thickness of the second material layer 420 is controlled to be greater than or equal to 4 nm, the multi-channel characteristics of the channel structure 400 that will be described below may not be expressed.

The forming of the first material layer 410 (S200) and the forming of the second material layer 420 (S300) may be alternately repeated so as to manufacture the channel structure 400. In other words, the channel structure 400 may have a structure in which the first material layer 410 and the second material layer 420 are alternately and repeatedly stacked.

According to one embodiment, a structure in which the first material layer 410 and the second material layer 420 are stacked may be defined as a stack. Accordingly, the channel structure 400 may have a structure in which a plurality of stacks are stacked.

Since the stacks are stacked, the channel structure 400 may form a multi-channel. In detail, the channel structure 400 in which the stacks are stacked may be configured such that carriers may move through each of a plurality of first material layers 410. The second material layer 420 may act as an insulating layer between adjacent first material layers 410.

A transistor to which the channel structure 400 is applied may have threshold voltage (Vₜₕ), mobility (UEE), and subthreshold swing (SS) characteristics controlled according to the stacking number of the stacks.

According to one embodiment, as the stacking number of the stacks increases, a threshold voltage (Vₜₕ) may be maintained substantially constant, whereas mobility (UE) and subthreshold swing (SS) may increase. In addition, an increase rate of the mobility (UE) according to the increase in the stacking number of the stacks may be higher than an increase rate of the subthreshold swing (SS).

According to one embodiment, in order to ensure high mobility and high reliability of the transistor to which the channel structure 400 is applied, the stacking number of the stacks may be controlled. In detail, the number of the stacks may be controlled to be greater than equal to 5, and less than or equal to 10.

According to the transistor to which the channel structure 400 with the stacks in the above-described range (5 to 10) being stacked is applied, a variation in the threshold voltage (Vₜₕ) according to the increase in the stacking number of the stacks may be maintained at 10% or less. In detail, the threshold voltage (Vₜₕ) may be maintained in a range of 0.09 V to 0.19 V despite the increase in the stacking number of the stacks. On the contrary, as the stacking number of the stacks increases, the mobility (UFE) and the subthreshold swing (SS) may be improved.

In other words, since the channel structure according to the embodiment of the present invention is manufactured through a PEALD process, a thickness and a composition may be easily controlled, and a high mobility characteristic may be effectively expressed through the control of the thickness and the composition. In addition, subthreshold swing (SS) may be easily controlled, and a threshold voltage (Vₜₕ) may be maintained substantially constant despite controlling mobility (UEE) and the subthreshold swing (SS). Accordingly, the channel structure may be easily applied to transistors in display back-planes that require high mobility and high reliability.

The channel structure and the method for manufacturing the same according to the embodiment of the present invention have been described above. Hereinafter, a thin film transistor to which the channel structure according to the embodiment of the present invention is applied will be described.

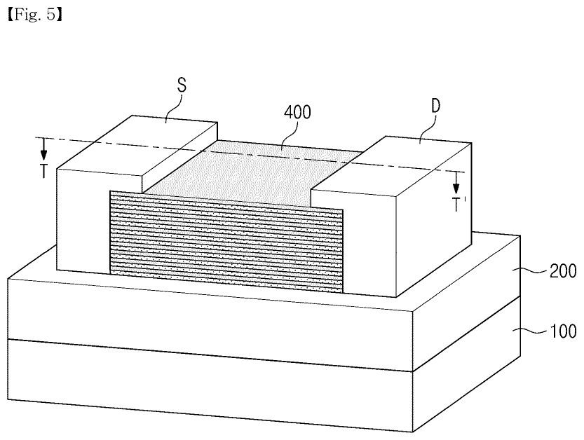

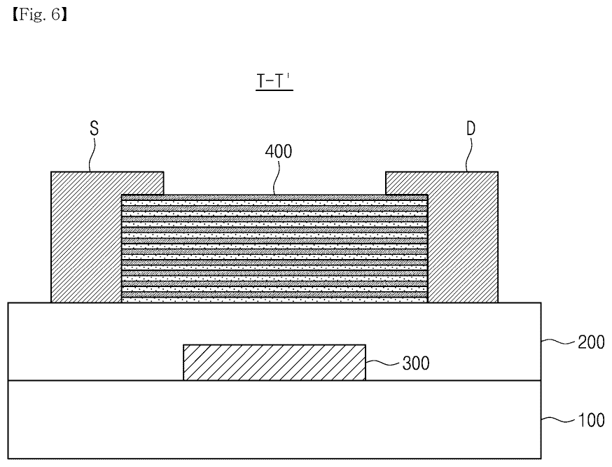

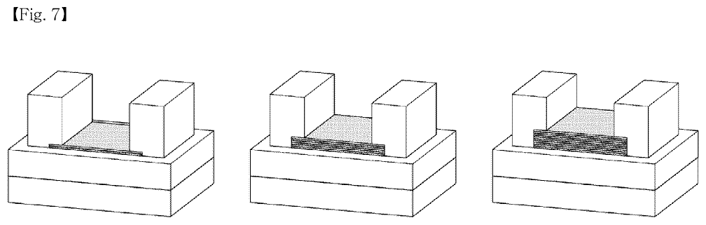

FIG. 5 is a view for describing a thin film transistor according to an embodiment of the present invention, FIG. 6 is a schematic view showing a T-T′ section of FIG. 5, and FIG. 7 is a view for describing various forms of a channel structure included in the thin film transistor according to the embodiment of the present invention.

Referring to FIGS. 5 and 6, the thin film transistor according to the embodiment may include: a substrate 100; a gate 300 disposed on the substrate 100; a gate insulating layer 200 disposed on the substrate 100, and covering the gate 300; a channel structure 400 disposed on the gate insulating layer 200; a source S disposed on the gate insulating layer 200, and making contact with one side of the channel structure 400; and a drain D disposed on the gate insulating layer 200, and making contact with an opposite side of the channel structure 400.

According to one embodiment, the channel structure 400 may be identical to the channel structure 400 described with reference to FIGS. 1 to 4. In other words, the thin film transistor according to the embodiment may have a structure in which the channel structure 400 is applied to a thin film transistor having a bottom gate structure. Alternatively, according to another embodiment, the channel structure 400 may also be applied to a thin film transistor having a top gate structure. As shown in FIG. 7, the channel structure 400 may have various thicknesses depending on the stacking number of the stacks.

According to the thin film transistor, the channel structure 400 may form a multi-channel. In detail, according to the thin film transistor, the carriers may move through each of the first material layers 410 included in the channel structure 400.

However, amounts of movement of the carriers within the first material layers 410 may be different from each other. In detail, an amount of movement of carriers within the first material layer 410 that is arranged relatively close to the gate 300 may be greater than an amount of movement of carriers within the first material layer 410 that is arranged relatively far from the gate 300. In other words, the first material layer 410 that is arranged relatively close to the gate 300 may be formed as a main channel, and the first material layer 410 that is arranged relatively far from the gate 300 may be formed as a sub-channel.

As described above, the stacking number of the stacks constituting the channel structure 400 may be controlled so as to easily control characteristics (mobility and subthreshold swing) of the thin film transistor, so that the thin film transistor may be easily applied to a back-plane of a display.

In detail, the thin film transistor may be applied to a switching TFT and a driving TFT of the display back-plane. However, the switching TFT and the driving TFT may have different stacking numbers of the channel structure 400. For example, a channel structure 400 having one stack may be used for the switching TFT. On the contrary, a channel structure 400 having 10 stacks may be used for the driving TFT.

Since a fast on/off characteristic is important for the switching TFT, lower subthreshold swing (SS) may be advantageous. Accordingly, the channel structure 400 having one stack may be used to improve the fast on/off characteristic of the switching TFT.

Meanwhile, since reading of a current value is important for the driving TFT, higher mobility (ME) may be advantageous. Accordingly, the channel structure 400 having 10 stacks may be used to improve characteristics of the driving TFT. In addition, since the channel structure 400 having 10 stacks has high subthreshold swing (SS), the current value may be subdivided and read at micro-voltages, so that the channel structure 400 may be advantageous in lower power consumption.

The thin film transistor according to the embodiment of the present invention has been described above. Hereinafter, specific experimental examples of the channel structure and the thin film transistor according to the embodiment of the present invention will be described.

### Manufacture of Channel Structure According to Experimental Example

An IGZO material layer was formed on a substrate by a plasma-enhanced atomic layer deposition (PEALD) process, and an Al₂O₃ material layer was formed on the IGZO material layer by a PEALD process.

In detail, (3-dimethylaminopropyl)dimethylindium (DADI) was used as an indium precursor, trimethylgallium (TMGa) was used as a gallium precursor, diethylzinc (DEZ) was used as a zinc precursor, trimethyl aluminum (TMA) was used as an aluminum precursor, and oxygen plasma (O₂ plasma) was used as a reactant. The oxygen plasma (O₂ plasma) was provided at a power of 100 W, and the PEALD process was performed at 200° C.

In addition, a structure in which the IGZO material layer and the Al₂O₃ material layer are stacked was defined as one stack (1 stack), and a total of 10 stacks (10 stack) were stacked to manufacture a channel structure according to an experimental example.

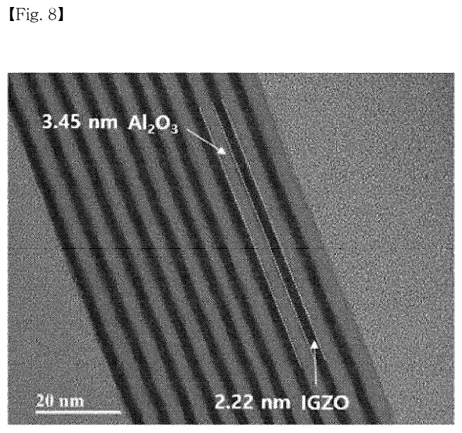

FIG. 8 is a STEM image of a channel structure according to an experimental example of the present invention.

Referring to FIG. 8, a scanning transmission electron microscope (STEM) image of the channel structure according to the experimental example is shown. As shown in FIG. 8, it may be found that the channel structure has a structure in which the IGZO material layer and the Al₂O₃ material layer are alternately and repeatedly stacked. In addition, it may be found that the IGZO material layer has a thickness of 2.22 nm, and the Al₂O₃ material layer has a thickness of 3.45 nm.

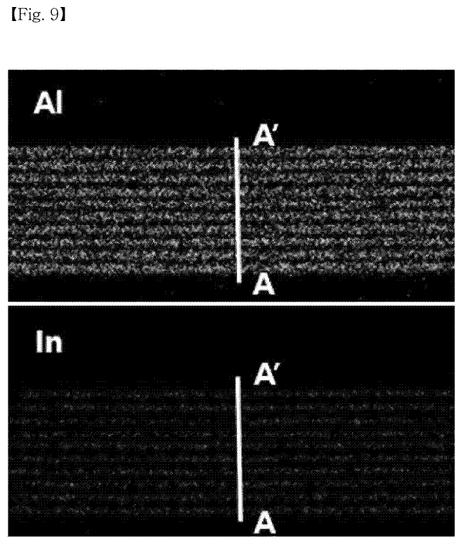

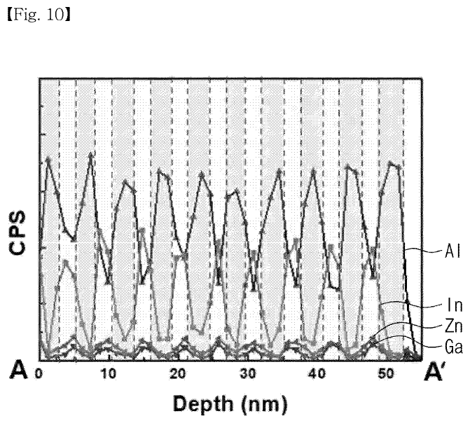

FIGS. 9 and 10 are views for describing EDS analysis results of the channel structure according to the experimental example of the present invention.

Referring to FIG. 9, energy dispersive X-ray spectroscopy (EDS) analysis results of the channel structure according to the experimental example are shown, and referring to FIG. 10, EDS line scan results are shown.

Composition distribution of the IGZO material layer and the Al₂O₃ material layer may be found through FIG. 9, and it may be found through FIG. 10 that the IGZO material layer and the Al₂O₃ material layer are stacked in 1D distribution.

### Preparation of Thin Film Transistor According to Experimental Example 1-1

A thin film transistor having a bottom gate structure and to which the channel structure according to the experimental example is applied was prepared, in which the channel structure has one stack.

### Preparation of Thin Film Transistor According to Experimental Example 1-2

A thin film transistor having a bottom gate structure and to which the channel structure according to the experimental example is applied was prepared, in which the channel structure has three stacks.

### Preparation of Thin Film Transistor According to Experimental Example 1-3

A thin film transistor having a bottom gate structure and to which the channel structure according to the experimental example is applied was prepared, in which the channel structure has five stacks.

### Preparation of Thin Film Transistor According to Experimental Example 1-4

A thin film transistor having a bottom gate structure and to which the channel structure according to the experimental example is applied was prepared, in which the channel structure has 10 stacks.

### Preparation of Thin Film Transistor According to Experimental Example 1-5

A thin film transistor having a bottom gate structure and to which the channel structure according to the experimental example is applied was prepared, in which the channel structure has 12 stacks.

### Preparation of Thin Film Transistor According to Experimental Example 1-6

A thin film transistor having a bottom gate structure and to which the channel structure according to the experimental example is applied was prepared, in which the channel structure has 14 stacks.

### Preparation of Thin Film Transistor According to Experimental Example 1-7

A thin film transistor having a bottom gate structure and to which the channel structure according to the experimental example is applied was prepared, in which the channel structure has 16 stacks.

### Preparation of Thin Film Transistor According to Experimental Example 1-8

A thin film transistor having a bottom gate structure and to which the channel structure according to the experimental example is applied was prepared, in which the channel structure has 18 stacks.

### Preparation of Thin Film Transistor According to Experimental Example 1-9

A thin film transistor having a bottom gate structure and to which the channel structure according to the experimental example is applied was prepared, in which the channel structure has 20 stacks.

TABLE 1

| Classification | Number of stacks |
|---|---|
| Experimental Example 1-1 | 1 |
| Experimental Example 1-2 | 3 |
| Experimental Example 1-3 | 5 |
| Experimental Example 1-4 | 10 |
| Experimental Example 1-5 | 12 |
| Experimental Example 1-6 | 14 |
| Experimental Example 1-7 | 16 |
| Experimental Example 1-8 | 18 |
| Experimental Example 1-9 | 20 |

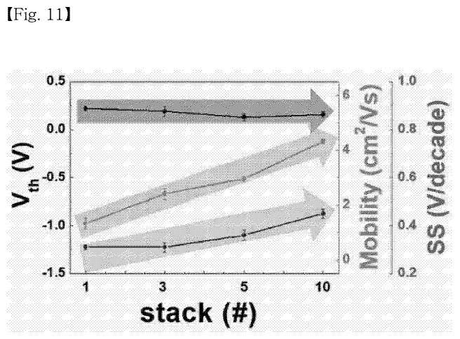

FIG. 11 is a view for describing electrical characteristics of thin film transistors according to Experimental Examples 1-1 to 1-4 of the present invention.

Referring to FIG. 11, a threshold voltage (Vₜₕ, V), mobility (μ_{FE}, cm²/Vs), and subthreshold swing (SS, V/decade) are measured and shown for each of the thin film transistors according to Experimental Examples 1-1 to 1-4.

As shown in FIG. 11, it may be found that the mobility and the subthreshold swing increase as the stacking number of the stacks constituting the channel structure increases (1→10). On the contrary, it may be found that the threshold voltage is maintained substantially constant despite the increase in the stacking number of the stacks. In addition, it may be found that an increase rate of the mobility according to the increase in the stacking number of the stacks is higher than an increase rate of the subthreshold swing. Specific measurement values are summarized in <Table 2> below.

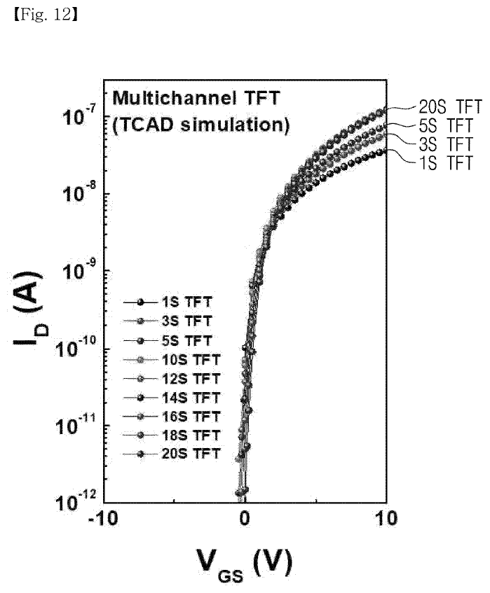

FIG. 12 is a view for comparing TCAD simulation results of thin film transistors according to Experimental Examples 1-1 to 1-9 of the present invention.

Referring to FIG. 12, TCAD simulation was performed on each of the thin film transistors according to Experimental Examples 1-1 to 1-9 to measure a threshold voltage (Vₜₕ, V), mobility (μ_{FE}, cm²/Vs), and subthreshold swing (SS, V/decade). Specific measurement values are summarized in <Table 2> below. In other words, in <Table 2>, Experimental Examples 1-1 to 1-4 show values that are actual measured, and Experimental Examples 1-5 to 1-9 show values measured through the TCAD simulation.

TABLE 2

| | Threshold | Mobility | Subthreshold |
|---|---|---|---|
| | voltage | (μ_{FE}, | swing (SS, |
| Classification | (Vₜₕ, V) | cm²/Vs) | V/decade) |
| Experimental Example | 0.22 ± 0.02 | 1.34 ± 0.21 | 0.31 ± 0.01 |
| 1-1 (1 stack) | | | |
| Experimental Example | 0.19 ± 0.05 | 2.40 ± 0.19 | 0.31 ± 0.02 |
| 1-2 (3 stack) | | | |
| Experimental Example | 0.13 ± 0.04 | 2.94 ± 0.10 | 0.36 ± 0.02 |
| 1-3 (5 stack) | | | |
| Experimental Example | 0.16 ± 0.03 | 4.33 ± 0.08 | 0.45 ± 0.02 |
| 1-4 (10 stack) | | | |
| Experimental Example | 0.41 | 3.57 | 0.47 |
| 1-5 (12 stack) | | | |
| Experimental Example | 0.44 | 3.41 | 0.46 |
| 1-6 (14 stack) | | | |
| Experimental Example | 0.47 | 3.38 | 0.46 |
| 1-7 (16 stack) | | | |
| Experimental Example | 0.63 | 3.37 | 0.47 |
| 1-8 (18 stack) | | | |
| Experimental Example | 1.27 | 3.10 | 0.46 |
| 1-9 (20 stack) | | | |

As shown in <Table 2>, it may be found that the mobility increases (1.34-4.33 cm²/Vs) when the number of stacks increases from 1 to 10, whereas the mobility decreases (4.33-3.10 cm²/Vs) when the number of stacks is greater than 10. In addition, it may be found that the subthreshold swing increases (0.31-0.45 V/decade) when the number of stacks increases from 1 to 10, whereas the subthreshold swing becomes substantially constant (0.45 to 0.47 V/decade) when the number of stacks is greater than 10. Further, it may be found that the threshold voltage is maintained substantially constant (0.13 to 0.22 V) when the number of stacks increases from 1 to 10, whereas the threshold voltage increases (0.16-1.27 V) when the number of stacks is greater than 10.

Therefore, it may be found that in order to increase the mobility and the subthreshold swing through the increase in the number of stacks while maintaining the threshold voltage substantially constant, the stacking number of the stacks has to be controlled to be less than or equal to 10.

In addition, it may be found that in order to have high mobility and easily control the subthreshold swing while maintaining the threshold voltage substantially constant, the stacking number of the stacks has to be controlled to be greater than equal to 5, and less than or equal to 10.

In detail, it may be found that when the stacking number of the stacks is controlled to be greater than equal to 5 and less than or equal to 10, the threshold voltage is maintained in a range of a minimum of 0.09 V to a maximum of 0.19 V so as to have a variation of 10% or less despite the increase in the number or stacks, whereas the mobility has a value of a maximum of 4.41 cm²/Vs, which is high mobility, and the subthreshold swing is controlled from a minimum of 0.34 V/decade to a maximum of 0.47 V/decade.

### Preparation of Thin Film Transistor According to Experimental Example 2-1

A thin film transistor having a bottom gate structure and to which the channel structure according to the experimental example is applied was prepared, in which the channel structure has three stacks.

In addition, an IGZO material layer was prepared to have a thickness of 1 nm, and an Al₂O₃ material layer was prepared to have a thickness of 3 nm.

### Preparation of Thin Film Transistor According to Experimental Example 2-2

A thin film transistor having a bottom gate structure and to which the channel structure according to the experimental example is applied was prepared, in which the channel structure has three stacks.

In addition, an IGZO material layer was prepared to have a thickness of 2 nm, and an Al₂O₃ material layer was prepared to have a thickness of 3 nm.

### Preparation of Thin Film Transistor According to Experimental Example 2-3

A thin film transistor having a bottom gate structure and to which the channel structure according to the experimental example is applied was prepared, in which the channel structure has three stacks.

In addition, an IGZO material layer was prepared to have a thickness of 3 nm, and an Al₂O₃ material layer was prepared to have a thickness of 3 nm.

### Preparation of Thin Film Transistor According to Experimental Example 2-4

A thin film transistor having a bottom gate structure and to which the channel structure according to the experimental example is applied was prepared, in which the channel structure has three stacks.

In addition, an IGZO material layer was prepared to have a thickness of 2 nm, and an Al₂O₃ material layer was prepared to have a thickness of 1 nm.

### Preparation of Thin Film Transistor According to Experimental Example 2-5

A thin film transistor having a bottom gate structure and to which the channel structure according to the experimental example is applied was prepared, in which the channel structure has three stacks.

In addition, an IGZO material layer was prepared to have a thickness of 2 nm, and an Al₂O₃ material layer was prepared to have a thickness of 3 nm.

### Preparation of Thin Film Transistor According to Experimental Example 2-6

A thin film transistor having a bottom gate structure and to which the channel structure according to the experimental example is applied was prepared, in which the channel structure has three stacks.

In addition, an IGZO material layer was prepared to have a thickness of 2 nm, and an Al₂O₃ material layer was prepared to have a thickness of 5 nm.

TABLE 3

| | Number | Thickness of | Thickness of |
|---|---|---|---|
| | of | IGZO material | Al₂O₃ material |
| Classification | stacks | layer | layer |
| Experimental Example 2-1 | 3 | 1 | 3 |
| Experimental Example 2-2 | 3 | 2 | 3 |
| Experimental Example 2-3 | 3 | 3 | 3 |
| Experimental Example 2-4 | 3 | 2 | 1 |
| Experimental Example 2-5 | 3 | 2 | 3 |
| Experimental Example 2-6 | 3 | 2 | 5 |

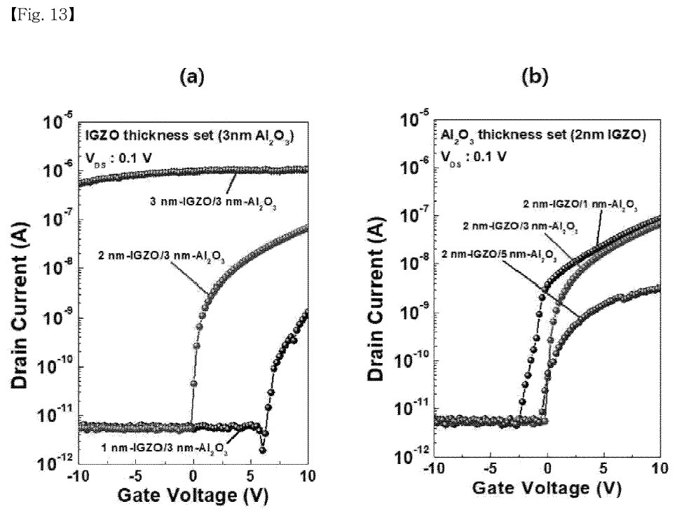

FIG. 13 is a view for describing electrical characteristics of thin film transistors according to Experimental Examples 2-1 to 2-6 of the present invention.

FIG. 13(a) shows electrical characteristics of the thin film transistors according to Experimental Examples 2-1 to 2-3, and FIG. 13(b) shows electrical characteristics of the thin film transistors according to Experimental Examples 2-4 to 2-6.

As shown in FIG. 13(a), it may be found that when the thickness of the Al₂O₃ material layer is fixed at 3 nm, and the thickness of the IGZO material layer varies from 1 nm to 3 nm, the electrical characteristics of the thin film transistor (Experimental Example 2-2) including the IGZO material layer having the thickness of 2 nm are the highest.

As shown in FIG. 13(b), it may be found that when the thickness of the IGZO material layer is fixed at 2 nm, and the thickness of the Al₂O₃ material layer varies from 1 nm to 5 nm, the electrical characteristics decrease according to the increase in the thickness of the Al₂O₃ material layer. Electrical characteristic measurement results of the thin film transistors according to Experimental Examples 2-4 to 2-6 are summarized in <Table 4> below.

TABLE 4

| | Experimental | Experimental | Experimental |
|---|---|---|---|
| Classification | Example 2-4 | Example 2-5 | Example 2-6 |
| Vₜₕ [V] | −1.21 ± 0.08 | 0.19 ± 0.05 | 1.01 ± 0.12 |
| μ_{FE} [cm²/Vs] | 2.53 ± 0.31 | 2.40 ± 0.19 | 0.11 ± 0.01 |
| SS [V/decade] | 0.60 ± 0.03 | 0.31 ± 0.02 | 0.86 ± 0.03 |

### Preparation of Thin Film Transistor According to Experimental Example 3-1

A thin film transistor having a bottom gate structure and to which the channel structure according to the experimental example is applied was prepared, in which the channel structure has three stacks.

In addition, an IGZO material layer was prepared to have a thickness of 1 nm, and an Al₂O₃ material layer was prepared to have a thickness of 3 nm.

### Preparation of Thin Film Transistor According to Experimental Example 3-2

A thin film transistor having a bottom gate structure and to which the channel structure according to the experimental example is applied was prepared, in which the channel structure has three stacks.

In addition, an IGZO material layer was prepared to have a thickness of 4 nm, and an Al₂O₃ material layer was prepared to have a thickness of 3 nm.

### Preparation of Thin Film Transistor According to Experimental Example 3-3

A thin film transistor having a bottom gate structure and to which the channel structure according to the experimental example is applied was prepared, in which the channel structure has three stacks.

In addition, an IGZO material layer was prepared to have a thickness of 8 nm, and an Al₂O₃ material layer was prepared to have a thickness of 3 nm.

TABLE 5

| | Number | Thickness of | Thickness of |
|---|---|---|---|
| | of | IGZO material | Al₂O₃ material |
| Classification | stacks | layer | layer |
| Experimental Example 3-1 | 3 | 1 | 3 |
| Experimental Example 3-2 | 3 | 4 | 3 |
| Experimental Example 3-3 | 3 | 8 | 3 |

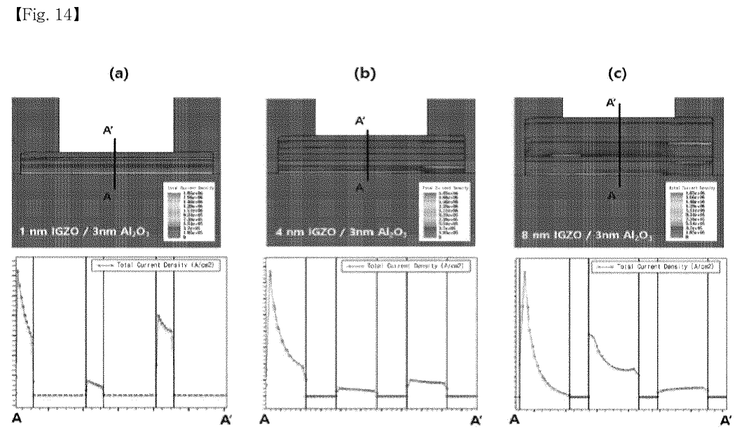

FIG. 14 is a view for describing simulation results of thin film transistors according to Experimental Examples 3-1 to 3-3 of the present invention.

Referring to FIG. 14, current density mapping simulation results are shown for each of the thin film transistors according to Experimental Examples 3-1 to 3-3. In detail, the results at VGs of 20 V and Vos of 20.1 V are shown.

As shown in FIG. 14, it may be found that when the thickness of the Al₂O₃ material layer is fixed at 3 nm, a multi-channel is easily formed even when the thickness of the IGZO material layer varies from 1 nm to 8 nm.

### Preparation of Thin Film Transistor According to Experimental Example 4-1

A thin film transistor having a bottom gate structure and to which the channel structure according to the experimental example is applied was prepared, in which the channel structure has three stacks.

In addition, an IGZO material layer was prepared to have a thickness of 2 nm, and an Al₂O₃ material layer was prepared to have a thickness of 1 nm.

### Preparation of Thin Film Transistor According to Experimental Example 4-2

A thin film transistor having a bottom gate structure and to which the channel structure according to the experimental example is applied was prepared, in which the channel structure has three stacks.

In addition, an IGZO material layer was prepared to have a thickness of 2 nm, and an Al₂O₃ material layer was prepared to have a thickness of 4 nm.

### Preparation of Thin Film Transistor According to Experimental Example 4-3

A thin film transistor having a bottom gate structure and to which the channel structure according to the experimental example is applied was prepared, in which the channel structure has three stacks.

In addition, an IGZO material layer was prepared to have a thickness of 2 nm, and an Al₂O₃ material layer was prepared to have a thickness of 8 nm.

TABLE 6

| | Number | Thickness of | Thickness of |
|---|---|---|---|
| | of | IGZO material | Al₂O₃ material |
| Classification | stacks | layer | layer |
| Experimental Example 4-1 | 3 | 2 | 1 |
| Experimental Example 4-2 | 3 | 2 | 4 |
| Experimental Example 4-3 | 3 | 2 | 8 |

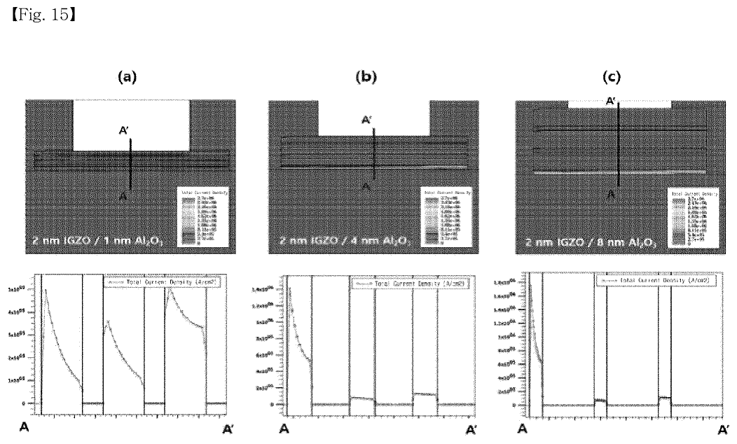

FIG. 15 is a view for describing simulation results of thin film transistors according to Experimental Examples 4-1 to 4-3 of the present invention.

Referring to FIG. 15, current density mapping simulation results are shown for each of the thin film transistors according to Experimental Examples 4-1 to 4-3. In detail, the results at VGs of 20 V and Vos of 20.1 V are shown.

As shown in FIG. 15, it may be found that a multi-channel is formed in the thin film transistor according to Experimental Example 4-1, whereas a multi-channel is not formed in the thin film transistors according to Experimental Examples 4-2 and 4-3. Accordingly, it may be found that the thickness of the Al₂O₃ material film has to be controlled to be less than 4 nm in order to form a multi-channel.

### Preparation of Thin Film Transistor According to Experimental Example 5-1

A thin film transistor having a bottom gate structure and to which the channel structure according to the experimental example is applied was prepared, in which the channel structure has three stacks.

In addition, an IGZO material layer was prepared to have a thickness of 1 nm, and an Al₂O₃ material layer was prepared to have a thickness of 1 nm.

### Preparation of Thin Film Transistor According to Experimental Example 5-2

A thin film transistor having a bottom gate structure and to which the channel structure according to the experimental example is applied was prepared, in which the channel structure has three stacks.

In addition, an IGZO material layer was prepared to have a thickness of 2 nm, and an Al₂O₃ material layer was prepared to have a thickness of 1 nm.

### Preparation of Thin Film Transistor According to Experimental Example 5-3

A thin film transistor having a bottom gate structure and to which the channel structure according to the experimental example is applied was prepared, in which the channel structure has three stacks.

In addition, an IGZO material layer was prepared to have a thickness of 5 nm, and an Al₂O₃ material layer was prepared to have a thickness of 1 nm.

TABLE 7

| | Number | Thickness of | Thickness of |
|---|---|---|---|
| | of | IGZO material | Al₂O₃ material |
| Classification | stacks | layer | layer |
| Experimental Example 5-1 | 3 | 1 | 1 |
| Experimental Example 5-2 | 3 | 2 | 1 |
| Experimental Example 5-3 | 3 | 5 | 1 |

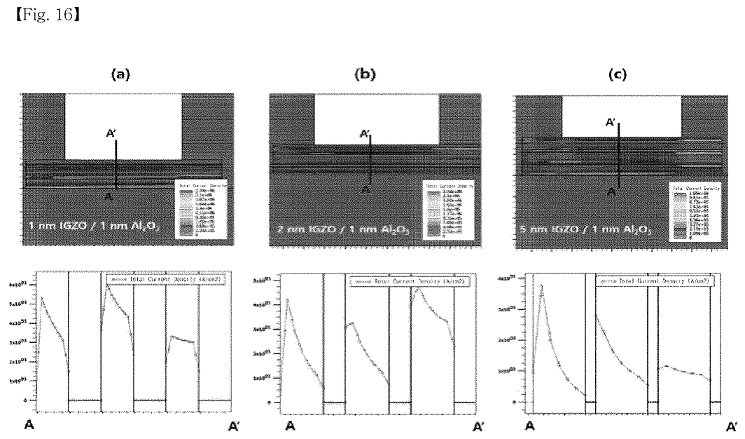

FIG. 16 is a view for describing simulation results of thin film transistors according to Experimental Examples 5-1 to 5-3 of the present invention.

Referring to FIG. 16, current density mapping simulation results are presented for each of the thin film transistors according to Experimental Examples 5-1 to 5-3. In detail, the results at Vs of 20 V and Vos of 20.1 V are shown.

As shown in FIG. 16, it may be found that when the thickness of the Al₂O₃ material layer is fixed at 1 nm, formation of a multi-channel becomes more difficult as the thickness of the IGZO material layer increases.

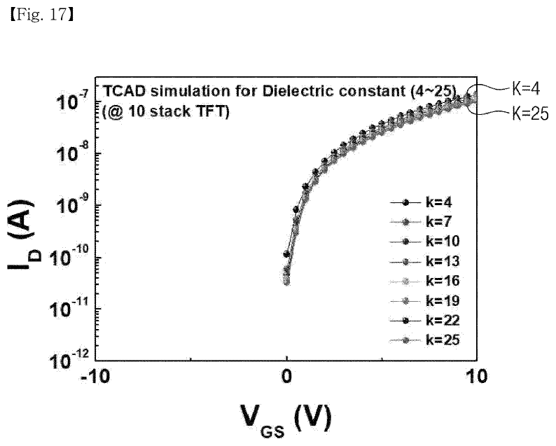

FIG. 17 is a graph for comparing electrical characteristics according to a k value of an insulator.

Referring to FIG. 17, according to a channel structure having a structure in which an oxide semiconductor and an insulator are stacked, a variation in electrical characteristics according to a k value of the insulator is shown through TCAD simulation results. As shown in FIG. 17, it may be found that the mobility tends to increase as the k value of the insulator decreases.

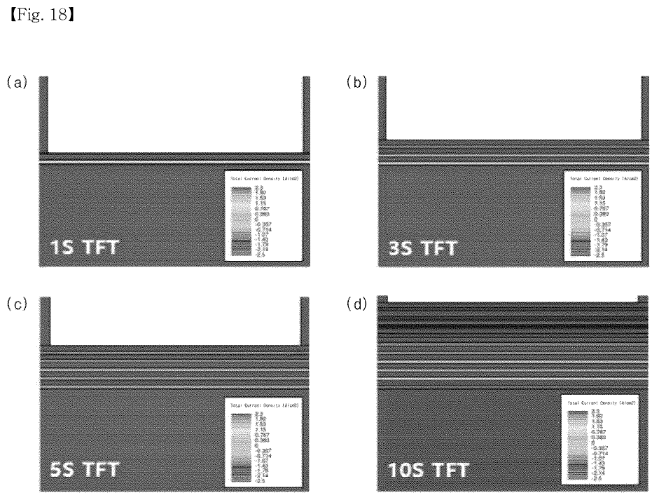

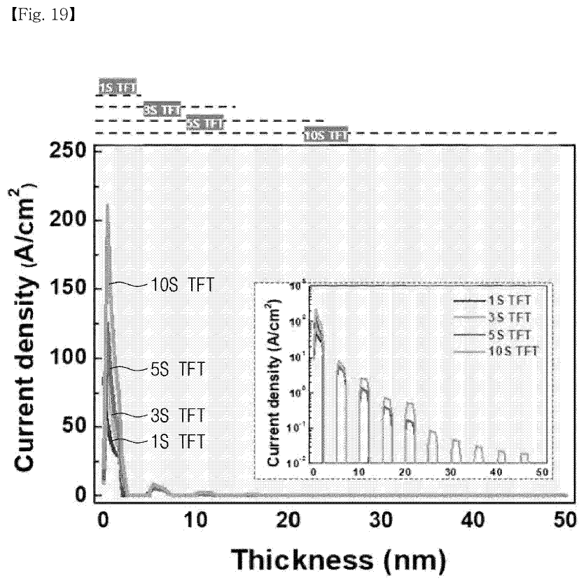

FIGS. 18 and 19 are views for comparing amounts of movement of carriers within channel structures of the thin film transistors according to Experimental Examples 1-1 to 1-4 of the present invention.

Referring to FIGS. 18 and 19, after preparing the thin film transistors according to Experimental Examples 1-1 to 1-4, simulation results for amounts of movement of carriers within respective channel structure are shown. In detail, FIG. 18(a) shows the result of Experimental Example 1-1, FIG. 18(b) shows the result of Experimental Example 1-2, FIG. 18(c) shows the result of Experimental Example 1-3, and FIG. 18(d) shows the result of Experimental Example 1-4.

As shown in FIGS. 18 and 19, it may be found that a relatively large amount of carriers move in the IGZO material layer that is arranged relatively close to the gate, and a relatively small amount of carriers move in the IGZO material layer that is arranged relatively far from the gate.

Although the exemplary embodiments of the present invention have been described in detail above, the scope of the present invention is not limited to a specific embodiment, and shall be interpreted by the appended claims. In addition, it is to be understood by a person having ordinary skill in the art that various changes and modifications can be made without departing from the scope of the present invention.

### INDUSTRIAL APPLICABILITY

The present invention may be used in the semiconductor industry.

1. A thin film transistor including a channel structure in which a first material layer including an oxide semiconductor and a second material layer including a metal oxide insulator are stacked,
wherein the channel structure forms a multi-channel by stacking a plurality of stacks, in which the first material layer and the second material layer are stacked in each of the stacks, and
mobility and subthreshold swing increase as a stacking number of the stacks increases.

2. The thin film transistor of claim 1, wherein an increase rate of the mobility according to the increase in the stacking number of the stacks is higher than an increase rate of the subthreshold swing.

3. The thin film transistor of claim 1, wherein a variation in a threshold voltage is maintained at 10% or less even when the stacking number of the stacks increases.

4. The thin film transistor of claim 3, wherein the threshold voltage is maintained in a range of 0.09 V to 0.19 V even when the stacking number of the stacks increases.

5. The thin film transistor of claim 1, wherein the stacking number of the stacks is greater than equal to 5, and less than or equal to 10.

6. The thin film transistor of claim 1, wherein a thickness of the second material layer is less than 4 nm.

7. The thin film transistor of claim 1, wherein the oxide semiconductor includes indium gallium zinc oxide (IGZO).

8. The thin film transistor of claim 1, wherein the metal oxide insulator includes aluminum oxide (Al₂O₃).

9. The thin film transistor of claim 1, wherein an amount of movement of carriers within the first material layer that is arranged relatively close to a gate is greater than an amount of movement of carriers within the first material layer that is arranged relatively far from the gate.

10. A method for manufacturing a channel structure, the method comprising:
preparing a substrate;
forming a first material layer including an oxide semiconductor on the substrate by a plasma-enhanced atomic layer deposition (PEALD) process; and
forming a second material layer including a metal oxide insulator on the first material layer by a PEALD process,
wherein the forming of the first material layer and the forming of the second material layer are alternately repeated so as to form a multi-channel.

11. The method of claim 10, wherein the forming of the first material layer includes:
reacting an indium (In) precursor, a gallium (Ga) precursor, a zinc (Zn) precursor, and oxygen plasma (O₂ plasma) on the substrate, and
the forming of the second material layer includes:
reacting an aluminum (Al) precursor and oxygen plasma (O₂ plasma) on the first material layer.

12. The method of claim 10, wherein the first material layer and the second material layer are formed by an in-situ process.
